(19) United States
(12) Patent Application Publication
(10) Pub. No.: US 2026/0020205 A1
(43) Pub. Date: Jan. 15, 2026

(54) SHIELDING COMBINING PRESS-FIT WITH SURFACE MOUNT COMPRESSION

(71) Applicant: Aptiv Technologies AG, Schaffhausen (CH)

(72) Inventors: Gert DROESBEKE, Erkrath (DE); Daniel HACKBARTH, München (DE); Phil M. DANCISON, Cortland, OH (US)

(21) Appl. No.: 19/263,772

(22) Filed: Jul. 9, 2025

Related U.S. Application Data
(60) Provisional application No. 63/668,833, filed on Jul. 9, 2024.

(30) Foreign Application Priority Data
Jul. 19, 2024 (EP) 24189803.0

(51) Int. Cl. H05K 9/00

(52) U.S. Cl. CPC H05K 9/0024

(57) ABSTRACT

An EMC shield for providing electromagnetic compatibility of electronic components includes a wall formed with an interface portion having at least one coplanar edge; a mounting member configured to secure the EMC shield to a printed circuit board (PCB) such that, when mounted, the interface portion is substantially parallel to the PCB; and a contact member, distinct from the mounting member, integrated with the wall and extending outwardly from the interface portion in the mounting direction. The contact member is configured to exert a contact pressure on the PCB along the mounting direction when the EMC shield is mounted, thereby enhancing electromagnetic sealing between the shield and the PCB.

### CROSS-REFERENCE TO RELATED APPLICATION

This application claims the benefit of and priority to U.S. Provisional Application No. 63/668,833 filed on Jul. 9, 2024, and European Application No. 24189803.0 filed with the European Patent Office on Jul. 19, 2024, the contents of each of which are incorporated by reference herein.

### TECHNICAL FIELD

The present disclosure generally relates to electromagnetic compatibility (EMC) shielding and more specifically to an EMC shield for providing electromagnetic compatibility of electronic components.

### BACKGROUND

Commonly, electromagnetic fields generated by electronic components may be required to stay confined within a restricted space surrounding such components.

Also, such fields may be required not to enter the electronic components from outside. Generally, electronic components include active components such as integrated circuits, discrete transistors, or the like, and passive components such as coils, cables, connectors, or the like. The rationale for the above reflected requirements includes avoiding mutual interference among electronic components/devices/units and/or ensuring compliance with regulatory (or customer) specifications. In general, various measures are known to facilitate electromagnetic compatibility (EMC) and limit electromagnetic interference (EMI). These measures include shielding electric and/or magnetic fields which aims at improving EMC/EMI properties. Shielding may be generally used with any electronic component being exposed to and/or generating high emissions of electromagnetic radiation. Shielding measures include placing electronic components at least partially within a shield which is formed from e.g., a piece of sheet metal.

In the field of communications, for example, internal communications within a vehicle, steadily increasing number of functions/features (e.g., autonomous driving) results in continuously growing demand for transferring data represented by electromagnetic signals. The increasing amount of data leads to increase in frequencies used for transferring data and, as a consequence, to decrease in wavelengths carrying data (since wavelength is inversely proportional to frequency). As a result, the maximum gap size allowed in the shielding generally becomes smaller in order for the shield to remain EMC/EMI compliant.

Ensuring a limited gap size is particularly challenging in the space immediately above the top metal layer of a printed circuit board (PCB). Even if reflow soldering is applied to obtain a non-interrupted connection between the top metal layer and the shield of an electronic component (such as the shield of a connector), certain gaps may be required to be left due to various considerations. For example, such gaps may be required for controlled distribution of solder paste (without solder balls or solder bridges after solder reflow). Further, for example, such gaps may be required for outgassing during the solder reflow process in order not to lift the electronic component. This is because typically about 50% of the solder paste is alcohol which vaporizes during the reflowing.

Furthermore, for a variety of reasons, press-fit mounting is often a preferred technique for mounting certain electronic components (such as the shield of a connector and/or the connector itself) to the PCB. For instance, the press-fit mounting generally provides the lowest total applied cost. Moreover, with regard to the assembling process of the PCB, the use of press-fit mounting typically conveniently separates mounting of the connector/shield (which uses the press-fit mounting) from mounting other components on the PCB. As a result, tiny semiconductors and other surface-mounted devices (SMD) may be assembled to the PCB without compromises and inefficiencies imposed by the presence on the PCB of bulky components (such as connectors/shields). In the above approach, the bulky components may be press-fitted onto the PCB after all other components have been reflow-soldered into the PCB.

On the other hand, however, press-fit mounting requires a hole to be drilled (or milled) though the PCB. A large number of such holes is generally undesirable. This is because, the less such holes are present, the more PCB surface remains available to place components, the more space/options remain available to route traces in copper layers of the PCB and the better cost/operation efficiency of the PCB manufacturing process (due to less cycle time, less copper consumption to metalize the holes, less down time to replace worn out or broken drills, etc.) is achieved. Finally, for the PCB to still have some strength and to be able to drill the holes with sufficient precision. A certain minimum amount of PCB material is to be maintained between the hole and the PCB edge or between successive holes.

In view of the above reflected background, the object of the presently disclosed subject matter is to provide an enhanced EMC shield for providing electromagnetic compatibility of electronic components which at least partially overcomes disadvantages attributable to prior art EMC shields and to have signal contacts suitable for higher data-transmissions.

### SUMMARY

Particularly, the above-mentioned objective is realized by an EMC shield providing electromagnetic compatibility of electronic components. The EMC shield includes at least one wall (e.g., formed from a single sheet of metal). The wall includes an interface portion (e.g., a plane for being directly or indirectly attached to a printed circuit board (PCB)). The interface portion includes (is defined by) a plurality of coplanar edges of the wall. Furthermore, the EMC shield includes a plurality of mounting means (e.g., press-fit means configured for insertion into the PCB) configured for mounting the EMC shield to the PCB. The mounting means are configured for mounting the EMC shield to the PCB such that, when the EMC shield is mounted to the PCB, the interface portion is substantially parallel (e.g., parallel within tolerances typically appliable in the art) to the PCB. The EMC shield includes furthermore at least one contact means which is different from the above-mentioned mounting means. The contact means is integrated with (e.g., formed within, formed as a part, or the like) the wall. The contact means at least partially extends outwards the interface portion in a mounting direction of the EMC shield to the PCB. The contact means is configured for providing, when the EMC shield is mounted to the PCB, a contact pressure between the contact means and the PCB along the mounting direction. In other words, the contact pressure is provided along a normal direction of the PCB. As a result, due to the contact pressure, the EMC shield advantageously reduces a gap size in the shielding and thereby enhances EMC/EMI properties since the contact means is positioned nearby (or in a direct electrical contact with) a top metal layer of the PCB without additional mounting features (e.g., press-fit means, soldering, or the like). In other words, the claimed subject matter may advantageously take advantage of the holding (retention) force provided by the mounting means while reducing the number of mounting means and still restraining the maximum gap size between the successive contact and/or mounting means and the top layer of the PCB by providing a normal force (and hence a contact pressure) onto the contact means besides the one already present in the mounting means.

In an aspect of the present disclosure, the contact pressure suffices (e.g., is designed to be just high enough under worst case conditions, not to stress & bow-out the PCB more as absolutely needed) to provide a gastight contact between the contact means and the top metal layer of the PCB. As a result, a gap size in the shielding may be advantageously further reduced. The gastight contact is preferably achieved by a cold weld between the contact means and the top metal layer of the PCB. As a result, the direct electric contact between the contact means and the top metal layer of the PCB may be advantageously more robust in terms of mechanical design and/or EMC/EMI performance.

In a further aspect of the present disclosure, the contact means includes a resilient means. The resilient means preferably includes at least one of a single ended contact beam, a double ended contact bow, an eye-of-the-needle shape, an H-shape/bow-tie shape or a bend castellation, and preferably wherein the bend castellation includes a material reduction at an inside bend radius. Such bend castellations could furthermore have angled separations/stamped slots between them and may be bent such that 2 shielding walls are positioned between the inside and the outside of the EMC shield, because to which an extra EMC labyrinth is created as most of these separations are now at least partially cover by metal of the shielding either in front or behind it. In other aspects of the present disclosure, the contact means includes a non-resilient means. The non-resilient means preferably includes at least one of a sharp castellation, a curved castellation, a rounded castellation, a flat area or a coined area (a line contact).

As a result, the shape of a contact means may be advantageously selected considering the amount of a holding (retention) force provided by the mounting means, the size of an allowable gap size for EMC/EMI purposes, the degree of resilience attributable to the shape and/or technological aspects of manufacturing the shape, for example, by stamping. In a non-limiting example, the bend castellation with a material reduction at the inside bend radius may advantageously enable a more compact design and/or less long slots besides the castellations and/or improve coplanarity across a sequence of castellations. In another non-limiting example, the sharp castellation may advantageously cut (bite) into the top metal layer of the PCB thereby creating an EMC labyrinth.

In a further aspect of the present disclosure, the at least one contact means includes at least two contact means selected from one, two or more resilient means and/or one, two or more non-resilient means. As a result, reduction in the gap size in the shielding may be advantageously further optimized.

In a further aspect of the present disclosure, the wall and the contact means are formed from a single sheet of metal, preferably by stamping. As a result, the EMC shield may be advantageously manufactured regarding optimizing complexity and costs.

In a further aspect of the present disclosure, the wall and the contact means have substantially the same (e.g., within tolerances typically appliable in the art) thickness. As a result, complexity and costs of manufacturing may be advantageously reduced. In another aspect of the present disclosure, the contact means are thinner than the wall. As a result, the contact means may be advantageously more compact.

In a further aspect of the present disclosure, the contact means includes a formed section. As a result, the contact means may be advantageously more compact and/or material may be advantageously displaced beyond the material thickness. In another aspect of the present disclosure, the contact means is located behind an overlapping section of the wall. As a result, colliding (e.g., hooking) of the contact means (e.g., the single ended contact beam) with another element may be advantageously prevented. In yet another aspect of the present disclosure, the contact means is located behind an insulator and/or a housing.

In a further aspect of the present disclosure, each of the plurality of mounting means is configured for a press-fit insertion into the PCB. As a result, holding (retention) force may be advantageously provided by the mounting means.

Further particularly, the above-mentioned object is realized by an electrical connector system. The electrical connector system includes a housing, a plurality of electrical contact elements arranged in the housing, and the above-described EMC shield. The electrical connector system preferably includes another EMC shield (i.e., a second EMC shield). The above-described EMC shield (i.e., a first EMC shield) is connected onto the second EMC shield. As a result, the above-described EMC shield may be advantageously manufactured from a separate piece of sheet metal and may be attached, for example, to another EMC shield (e.g., a shield of any existing design).

In a further aspect of the present disclosure, the second EMC shield is made of a sheet metal, diecast metal, sintered metal, an injection molded metal, a 3D-printed metal, metalized plastic, or conductive plastic. In yet another aspect of the present disclosure, the EMC shield is connected onto the second EMC shield by riveting, laser-welding, resistance welding, ultrasonic welding, soldering or gluing. As a result, robust and cost-efficient shielding may be advantageously provided.

### BRIEF DESCRIPTION OF THE DRAWINGS

In the following, preferred embodiments of the disclosure are disclosed by reference to the accompanying figures.

FIG. 1 shows a schematic view of an EMC shield in accordance with some embodiments.

FIG. 2A shows a schematic view of an EMC shield with a resilient contact means in accordance with some embodiments.

FIG. 2B shows a schematic view of an EMC shield with non-resilient contact means in accordance with some embodiments.

FIG. 3 shows a portion of an embodiment of an EMC shield with various contact means in accordance with some embodiments. in a cross-sectional view.

FIG. 4A shows an isometric view of an EMC shield in accordance with some embodiments.

FIG. 4B shows a front view of an EMC shield in accordance with some embodiments.

FIG. 5A shows an isometric view of an EMC shield in accordance with some embodiments.

FIG. 5B shows a front view of an EMC shield in accordance with some embodiments.

FIG. 6A shows an isometric view of an EMC shield in accordance with some embodiments.

FIG. 6B shows a front view of an EMC shield in accordance with some embodiments.

FIG. 7A shows an isometric view of an EMC shield in accordance with some embodiments.

FIG. 7B shows a front view of an EMC shield in accordance with some embodiments.

### DETAILED DESCRIPTION

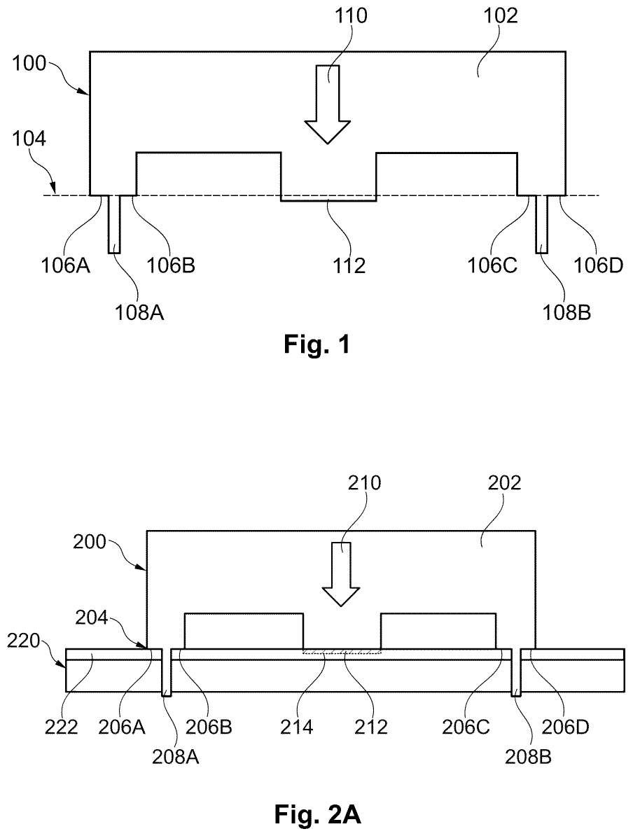

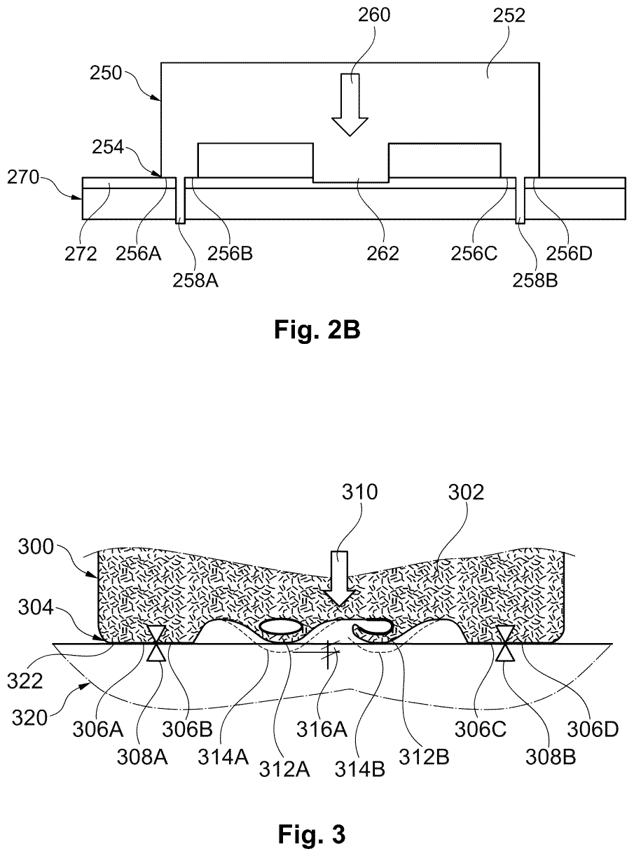

FIG. 1 shows an EMC shield 100 according to an embodiment of the present disclosure. The EMC shield 100 includes a wall 102. The wall 102 includes an interface portion 104 indicated by a dashed line. The interface portion 104 includes (is defined by) a plurality of coplanar edges 106A, 106B, 106C and 106D. The EMC shield 100 further includes a plurality of mounting means 108A and 108B configured for mounting the EMC shield 100 to a PCB (not shown in FIG. 1 but explained in conjunction with FIGS. 2A and 2B). The mounting means 108A and 108B are formed as pins (e.g., pins configured for a press-fit insertion into the PCB) and, when inserted into corresponding holes in the PCB, ensure that the interface portion 104 is substantially parallel (e.g., parallel within tolerances typically appliable in the art) to the PCB. The mounting direction of the EMC shield 100 to the PCB is indicated by an arrow 110.

The EMC shield 100 includes furthermore a contact means 112 which is integrated with (e.g., formed within, formed as a part, or the like) the wall 102. The contact means 112 extends outwards the interface portion 104 along the mounting direction indicated by the arrow 110. The contact means 112 is formed such that a contact pressure between the contact means 112 and the PCB (not shown) is provided along the mounting direction indicated by the arrow 110 when the EMC shield 100 is mounted to the PCB. In some aspects of the present disclosure, the contact pressure is designed to suffice (i.e., to be high enough) to provide a gastight contact between the contact means 112 and a top metal layer of the PCB. For example, the gastight contact may be achieved by a cold weld obtained between the contact means 112 and the top metal layer of the PCB.

In some aspects of the present disclosure, the contact means 112 may be resilient and hence may be formed to be compressed under the contact pressure. This aspect is further explained in conjunction with FIGS. 2A and 3 below. In other aspects of the present disclosure, the contact means 112 may be substantially non-resilient and hence may stay substantially not compressed under the contact pressure. This aspect is further explained in conjunction with FIG. 2B.

FIG. 2A shows an EMC shield 200 according to an embodiment of the present disclosure. The EMC shield 200 includes a wall 202, an interface portion 204, edges 206A, 206B, 206C and 206D, and mounting means 208A and 208B which correspond to analogous elements explained in conjunction with FIG. 1 above. In addition, FIG. 2A shows a PCB 220 having a top metal layer 222. The PCB 220 includes holes (with no separate reference sign assigned) into which the mounting means 208A and 208B are inserted. Analogously as in FIG. 1, the mounting direction of the EMC shield 200 to the PCB 220 is indicated by an arrow 210. As shown in FIG. 2A, the interface portion 204 of the EMC shield 200 is located on an upper edge of the PCB 220 (which is illustrated by the interface portion 204 and the upper edge being overlayed). However, in some aspects of the present disclosure, the interface portion 204 may be located at a certain distance from the upper edge of the PCB 220, for example, due to a filling material (not shown) located between the interface portion 204 and the upper edge of the PCB 220.

The EMC shield 200 includes furthermore a contact means 212 which is integrated with the wall 202. The contact means 212 is resilient and may, in some aspects of the present disclosure, be formed as a single ended contact beam (which is explained in conjunction with FIG. 3), a double ended contact bow, an eye-of-the-needle shape (which is explained in conjunction with FIG. 3), an H-shape/bow-tie shape, a bend castellation which may include a material reduction at an inside bend radius, or the like. The shape of the contact means 212 prior to mounting the EMC shield 200 to the PCB 220 (i.e., in not compressed state) is schematically indicated by a dashed line 214.

Upon mounting the EMC shield 200 to the PCB 220, a contact pressure is provided between the contact means 212 and the PCB 220 along the mounting direction indicated by the arrow 210. The contact pressure acting upon the contact means 212 effectuates compression of the resilient contact means 212 such that the contact means 212 assumes a shape not cut into the PCB 220. In other words, the part of the EMC shield 200 which is designated by a shaded area in FIG. 2A is displaced due to compression (deformation) under the contact pressure acting upon the contact means 212. Positioning the contact means 212 near the top metal layer 222 (or, in some aspects of the present disclosure, providing a direct electrical contact between the contact means 212) enhances EMC/EMI properties of the EMC shield 200 by reducing a gap size in the shielding between successive contact and/or mounting means.

FIG. 2B shows an EMC shield 250 according to an embodiment of the present disclosure. The EMC shield 250 includes a wall 252, an interface portion 254, edges 256A, 256B, 256C and 256D, and mounting means 258A and 258B which correspond to analogous elements explained in conjunction with FIG. 1 above. In addition, FIG. 2B shows a PCB 270 having a top metal layer 272. The PCB 270 includes holes (with no separate reference sign assigned) into which the mounting means 258A and 258B are inserted. Analogously as in FIG. 1, the mounting direction of the EMC shield 250 to the PCB 270 is indicated by an arrow 260. Furthermore, analogously as in FIG. 2A, the interface portion 254 of the EMC shield 250 is located on an upper edge of the PCB 270 (which is illustrated by the interface portion 254 and the upper edge being overlayed). However, as explained in conjunction with FIG. 2A, in some aspects of the present disclosure, the interface portion 254 may be located at a certain distance from the upper edge of the PCB 270, for example, due to a filling material (not shown) located between the interface portion and the upper edge of the PCB 270.

The EMC shield 250 includes furthermore a contact means 262 which is integrated with the wall 252. The contact means 262 is non-resilient and may, in some aspects of the present disclosure, be formed as a sharp castellation, a curved castellation, a rounded castellation, a flat area, a coined area, or the like.

Upon mounting the EMC shield 250 to the PCB 270, a contact pressure is provided between the contact means 262 and the PCB 270 along the mounting direction indicated by the arrow 260. The contact pressure acting upon the contact means 262 effectively substantially causes no compression of the non-resilient means 262 such that the non-resilient means 262 cuts into the top metal layer 272 of the PCB 270 and thereby provides a direct electrical contact between the contact means 262 and the top metal layer 272. Although limited, the PCB will hereby bow out elastically by which tolerances can be absorbed. Providing the direct electrical contact between the contact means 262 and the top metal layer 272 enhances EMC/EMI properties of the EMC shield 250 by reducing a gap size in the shielding between successive contact and/or mounting means.

FIG. 3 shows in a two-dimensional view of a portion of an EMC shield 300 according to an embodiment of the present disclosure. The EMC shield 300 includes a wall 302, an interface portion 304, edges 306A, 306B, 306C and 306D, and mounting means 308A and 308B (represented symbolically) which correspond to analogous elements explained in conjunction with FIG. 1 above. In addition, FIG. 3 shows a portion of a PCB 320 having a top metal layer 322. Analogously as in FIG. 1, the mounting direction of the EMC shield 300 to the PCB 320 is indicated by an arrow 310.

The EMC shield 300 includes furthermore contact means 312A and 312B which are integrated with the wall 302. The contact means 312A is resilient and is formed as an eye-of-the-needle shape. The shape of the contact means 312A prior to mounting the EMC shield 300 to the PCB 320 (i.e., in not compressed state) is indicated by a line 314A. The amount of compression of the contact means 312A upon the mounting of the EMC shield 300 into the PCB 320 is indicated by a distance 316A. The contact means 312B is resilient and is formed as a single ended contact beam. The shape of the contact means 312B prior to mounting the EMC shield 300 to the PCB 320 (i.e., in not compressed state) is indicated by a line 314B.

Upon mounting the EMC shield 300 to the PCB 320, a contact pressure is provided between the respective contact means 312A and 312B and the PCB 320 along the mounting direction indicated by the arrow 310. The contact pressure acting upon the contact means 312A effectuates compression (deformation) of the eye-of-the-needle shape of the contact means 312A such that the contact means 312A assumes a shape not cut into the PCB 320. Analogously the contact pressure acting upon the contact means 312B effectuates compression (deformation) of the single ended contact beam of the contact means 312B such that the contact means 312B assumes a shape not cut into the PCB 320. Selection of a shape of a contact means generally involves various considerations including the amount of a holding (retention) force provided by mounting means (e.g., the mounting means 308A and 308B), the size of an allowable gap for EMC/EMI purposes, the degree of resilience attributable to the shape and/or technological aspects of manufacturing the shape, for example, by stamping.

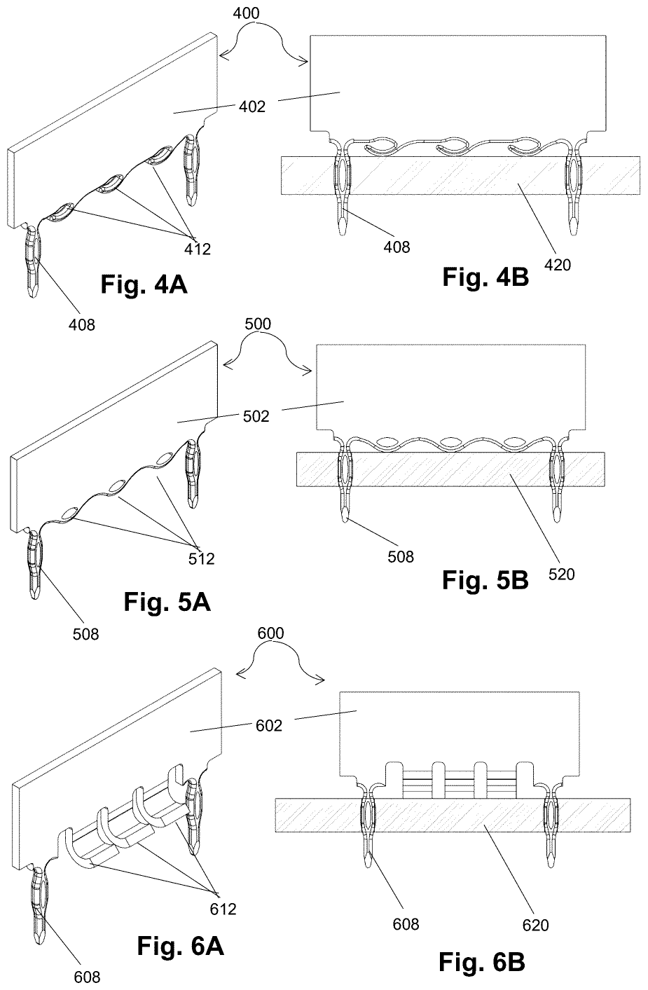

FIGS. 4 to 7 show four examples of possible embodiments for EMC shields, each shield having identical configuration except for the contact means, which are different for each embodiment.

FIG. 4A shows an isometric view of another embodiment of an EMC shield 400 and FIG. 4B shows a front view of the same EMC shield 400 assembled to a PCB 420. The EMC shield 400 includes two contact means 408 in the form of press-fit pins configured to be press-fitted into openings of the PCB 420. Such press-fit pins are in connection with PCBs are well known to the skilled person, so it is refrained from giving a detailed explanation thereof. The EMC shield 400 further includes three contact means 412 that include resilient means, in the form of a spiral-like contact beam.

FIGS. 5A and 5B show another embodiment of an EMC shield 500, including two mounting means 508, three contact means 512 and a wall 502. As with the other embodiments of FIGS. 4, 6 and 7, the EMC shield 500, the two mounting means 508 and the contact means 512 are integrally formed from a single piece of sheet metal. The contact means 512 include an eye-of-the-needle shape, which gives the contact means 512 resilient properties.

FIGS. 6A and 6B show yet another embodiment of an EMC shield 600, including two mounting means 608, three contact means 612 and a wall 602. Each contact means 612 is realized in form of a bend castellation.

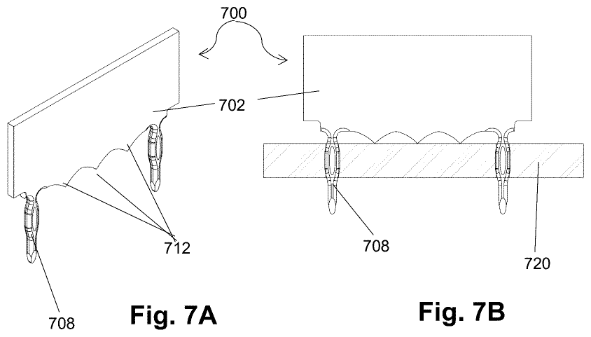

FIGS. 7A and 7B show yet another embodiment of an EMC shield 700, including two mounting means 708, three contact means 712 and a wall 702. Each contact means 712 is realized in form of a sharp castellation. In this embodiment, the contact means includes a non-resilient means.

While the invention has been described with reference to an exemplary embodiment(s), it will be understood by those skilled in the art that various changes may be made, and equivalents may be substituted for elements thereof without departing from the scope of the invention. In addition, many modifications may be made to configure a particular situation or material to the teachings of the invention without departing from the essential scope thereof. Therefore, it is intended that the invention is not limited to the disclosed embodiment(s), but that the invention will include all embodiments falling within the scope of the appended claims.

As used herein, ‘one or more’ includes a function being performed by one element, a function being performed by more than one element, e.g., in a distributed fashion, several functions being performed by one element, several functions being performed by several elements, or any combination of the above.

It will also be understood that, although the terms first, second, etc., are, in some instances, used herein to describe various elements, these elements should not be limited by these terms. These terms are only used to distinguish one element from another. For example, a first contact could be termed a second contact, and, similarly, a second contact could be termed a first contact, without departing from the scope of the various described embodiments. The first contact and the second contact are both contacts, but they are not the same contact.

The terminology used in the description of the various described embodiments herein is for the purpose of describing particular embodiments only and is not intended to be limiting. As used in the description of the various described embodiments and the appended claims, the singular forms “a”, “an”, and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

Additionally, while terms of ordinance or orientation may be used herein these elements should not be limited by these terms. All terms of ordinance or orientation, unless stated otherwise, are used for purposes distinguishing one element from another, and do not denote any particular order, order of operations, direction or orientation unless stated otherwise.

### LISTING OF REFERENCE NUMBERS

100 EMC shield
102 wall
104 interface portion
106A, 106B, 106C, 106D coplanar edges
108A, 108B mounting means
110 mounting direction
112 contact means
200 EMC shield
202 wall
204 interface portion
206A, 206B, 206C, 206D coplanar edges
208A, 208B mounting means
210 mounting direction
212 contact means
214 shape of contact means
220 PCB
222 top metal layer
250 EMC shield
252 wall
254 interface portion
256A, 256B, 256C, 256D coplanar edges
258A, 258B mounting means
260 mounting direction
262 contact means
270 PCB
272 top metal layer
300 EMC shield
302 wall
304 interface portion
306A, 306B, 306C, 306D coplanar edges
308A, 308B mounting means
310 mounting direction
312A, 312B contact means
314A, 314B shape of contact means
316A compression distance
320 PCB
322 top metal layer
400, 500, 600, 700 EMC shield
402, 502, 602, 702 wall
408, 508, 608, 708 mounting means
412, 512, 612, 712 contact means
420, 520, 620, 720 PCB

1. An electromagnetic compliance (EMC) shield, comprising:
at least one wall comprising an interface portion, the interface portion comprising at least one coplanar edge of the wall;
at least one mounting means configured for mounting the EMC shield to a printed circuit board (PCB), such that, when the EMC shield is mounted to the PCB, the interface portion is substantially parallel to the PCB; and
at least one contact means different from the mounting means, the contact means being integrated with the wall and at least partially extending outwards the interface portion in a mounting direction of the EMC shield to the PCB, the contact means being configured for providing a contact pressure between the contact means and the PCB along the mounting direction when the EMC shield is mounted to the PCB.

2. The EMC shield of claim 1, wherein the contact pressure suffices to provide a gastight contact between the contact means and a top metal layer of the PCB.

3. The EMC shield of claim 2, wherein the gastight contact is achieved by a cold weld between the contact means and the top metal layer of the PCB.

4. The EMC shield of claim 1, wherein the contact means comprises a resilient means.

5. The EMC shield of claim 4, wherein the resilient means comprises at least one selected from a list consisting of a spiral-like contact beam, a single ended contact beam, a double ended contact bow, an eye-of-the-needle shape, an H-shape/bow-tie shape, and a bend castellation.

6. The EMC shield of claim 5, the bend castellation comprises a material reduction at an inside bend radius.

7. The EMC shield of claim 1, wherein the contact means comprises a non-resilient means.

8. The EMC shield of claim 7, wherein the non-resilient means comprises at least one selected from a list consisting of a sharp castellation, a curved castellation, a rounded castellation, a flat area, and a coined area.

9. The EMC shield of claim 1, wherein the contact means comprises at least two contact means comprising one or more resilient means.

10. The EMC shield of claim 1, wherein the contact means comprises at least two contact means comprising one or more non-resilient means.

11. The EMC shield of claim 1, wherein the wall and the contact means are formed from a single sheet of metal.

12. The EMC shield of claim 11, wherein the wall and the contact means substantially have a same thickness.

13. The EMC shield of claim 11, wherein the contact means comprises a formed section and wherein the contact means is located behind an overlapping section of the wall.

14. The EMC shield of claim 11, wherein the contact means comprises a formed section and wherein the contact means is located behind an insulator and/or a housing.

15. The EMC shield of claim 1, wherein the at least one mounting means is configured for a press-fit insertion into the PCB.

16. The EMC shield of claim 1, wherein the contact means provides EMC functionality to an electrical connector system.

17. An electrical connector system comprising:
the EMC shield according to claim 1
a housing connected to the EMC shield; and
a plurality of electrical contact elements arranged in the housing.

18. The electrical connector system of claim 17, wherein the electrical connector system preferably further comprises a second EMC shield, wherein the EMC shield is connected onto the second EMC shield.

19. The electrical connector system of claim 18, wherein the second EMC shield is made of a material selected from a list consisting of sheet metal, diecast metal, sintered metal, injection molded metal, 3D-printed metal, metalized plastic, and conductive plastic.

20. The electrical connector system of claim 18, wherein the EMC shield is connected onto the second EMC shield by a process selected from a list consisting of riveting, laser-welding, resistance welding, ultrasonic welding, soldering, and gluing.
